(19) United States
(12) Patent Application Publication
(10) Pub. No.: US 2015/0268300 A1
(43) Pub. Date: Sep. 24, 2015

(54) SYSTEM AND AUTOMATED METHOD FOR MIXED-SIGNAL CIRCUIT FUNCTIONAL ANALYSIS

(71) Applicant: BAE SYSTEMS INFORMATION AND ELECTRONIC SYSTEMS INTEGRATION INC., Nashua, NH (US)

(72) Inventors: YUNBIN DENG, Westford, MA (US); VENKAT K. GOPALAKRISHNAN, Lexington, MA (US); RICK L. THOMPSON, Amherst, NH (US)

(73) Assignee: BAE SYSTEMS INFORMATION AND ELECTRONIC SYSTEMS INTEGRATION INC., Nashua, NH (US)

(21) Appl. No.: 14/191,473

(22) Filed: Feb. 27, 2014

Related U.S. Application Data
(60) Provisional application No. 61/852,361, filed on Mar. 14, 2013.

(51) Int. Cl. G01R 31/28; G01R 31/317

(52) U.S. Cl. CPC G01R 31/2834; G01R 31/317; G01R 31/31704; G01R 31/31724

(57) ABSTRACT

A system and automated method for mixed-signal circuit functional analysis is disclosed. In one embodiment, the method includes identifying hierarchical levels of functional components in an inputted mixed-signal circuit based on netlist, property of an input signal and a design knowledge base.

### CROSS-REFERENCE TO RELATED APPLICATIONS

This application claims rights under 35 USC §119(e) from U.S. Application 61/852,361 filed Mar. 14, 2013, the contents of which are incorporated herein by reference.

### STATEMENT OF GOVERNMENT INTEREST

The invention was made with United States Government support under Contract No. HR0011-11-C-0075 awarded by the Defense Advanced Research Projects Agency (DARPA). The United States Government has certain rights in this invention.

### BACKGROUND OF THE INVENTION

1. Field of the Invention

The present invention relates to a circuit analysis and more particularly to automatic mixed-signal circuit functional analysis.

2. Brief Description of Related Art

In general, integrated circuits (ICs) including both analog and digital signals can be referred to as mixed-signal circuits. As will be appreciated by the person skilled in the art, verification of the functionality of the mixed-signal circuits can be challenging. For example, verification of a mixed-signal circuit design given a datasheet and physical die is of great interest to the IC industry and critical importance to the military. Existing methods use testing to verify the functionality of the mixed-signal circuit design. However, this method may potentially overlook inserted malicious circuits in the mixed-signal chip.

Also, a thorough verification of a circuit design may require reverse engineering of a physical die to its functional building blocks, which requires two steps, i.e., from imaging to netlist (i.e., connection relationship of each terminal in the circuit design), and from netlist to function. Further, the unidentifiable circuits in this method may be further subjected to human examination. However, existing methods may be designed to perform circuit function analysis for either digital circuits or a part of linear analog circuits.

### SUMMARY OF THE INVENTION

A system and automated method for mixed-signal circuit functional analysis is disclosed. According to one aspect of the present subject matter, the method includes identifying hierarchical levels of functional components in an inputted mixed-signal circuit based on netlist, property of input signals and a design knowledge base. The design knowledge base is built in the form of hierarchical schematics and corresponding netlists. In one example embodiment, parallel and serial devices are merged in the inputted mixed-signal circuit. Further, voltage biases and current sources are identified at a first stage by comparing the netlist and the property of the input signal of the inputted mixed-signal circuit with subcircuit patterns in the design knowledge base. Furthermore, multiple lower levels of functional components are identified by comparing the netlist and property of input signals of the functional components with the subcircuit patterns in the design knowledge base. The signal properties of matched output at each level are assigned as the input to netlist's functional components in a next level.

For example, first level functional components are identified at a second stage by comparing the netlist and property of input signals of the first level functional components with the subcircuit patterns in the design knowledge base. The signal properties of matched output (i.e., outputs of matched voltage and/or current sources) of the first stage are assigned as the input to first level functional components in the second stage. Further, this process is repeated until all the levels of functional components are identified in the inputted mixed-signal circuit by assigning the matched output at each stage to netlist's functional components in a next stage. In addition, high level functional components of the inputted mixed-signal circuit can be identified by combining the identified functional components at each stage.

According to another aspect of the present subject matter, a system includes a processor and memory coupled to the processor, the memory including a mixed-signal circuit functional analysis module configured to perform the method for mixed-signal circuit functional analysis as described above.

According to yet another aspect of the present subject matter, a non-transitory computer-readable storage medium including instructions that are configured, when executed by a computing system, to perform a method for mixed-signal circuit functional analysis as described above.

### BRIEF DESCRIPTION OF THE DRAWINGS

The advantages and features of the present disclosure will become better understood with reference to the following detailed description and claims taken in conjunction with the accompanying drawings, wherein like elements are identified with like symbols, and in which:

FIG. 1 is a flow diagram of an automated method for mixed-signal circuit functional analysis, according to an embodiment of the present subject matter.

FIG. 2 illustrates an example schematic drawing showing a sub-circuit which can function as a differential amplifier or a current switch, depending on the nature of an input signal, in the context of the present subject matter.

FIG. 3(a) is a schematic drawing showing an example input mixed-signal circuit, in the context of the present subject matter.

FIG. 3(b) is a schematic drawing illustrating merging of parallel and serial devices in the input mixed-signal circuit of FIG. 3(a), according to an example embodiment of the present subject matter.

FIG. 3(c) is a schematic drawing illustrating identifying voltage bias in the input mixed-signal circuit of FIG. 3(b), according to an example embodiment of the present subject matter.

FIG. 3(d) is schematic drawing illustrating identifying current source in the input mixed-signal circuit of FIG. 3(c), according to an example embodiment of the present subject matter.

FIG. 3(e) is a schematic drawing illustrating identifying functional components in the input mixed-signal circuit of FIG. 3(d), according to an example embodiment of the present subject matter.

FIG. 4 is block diagram of an example physical computing system including mixed-signal circuit functional analysis module. according to an example embodiment.

### DETAILED DESCRIPTION OF THE INVENTION

The exemplary embodiments described herein in detail for illustrative purposes are subject to many variations in structure and design. The present technique provides a flexible framework for automatic mixed-signal circuit function analysis from an inferred flat netlist in the absence of a schematic ground truth. This can be achieved by building a mixed-signal circuit design knowledge base in the form of hierarchical schematics and corresponding net lists, including basic building blocks, amplifiers, and data converters and the like. This approach can dynamically incorporate new hierarchical circuit design knowledge into the mixed-signal circuit design knowledge base without software modification, thereby allowing circuit designers with different expertise to develop the knowledge base independently. Further, the present technique provides an enhanced sub-circuit matching technique that takes into account the nature of input signals to identify voltage bias, current-mirrors, switches, diff-amp, op-amp, high speed D/A converter and other key components of modern mixed-signal circuits. In addition, the proposed technique can also be used for probabilistic/approximate matching paradigm to extend sub-circuit matching under uncertainty from measured noisy data.

The key challenges in automatic mixed-signal circuit function analysis from extracted netlist are: 1) Mixed-signal circuit design is highly customized and there is no existing public standard mixed-signal circuit library, as compared to the digital counterpart. To overcome this, the present technique proposes developing of a complete mixed-signal design knowledge base, which is explained below. 2) The function of a mixed-signal sub-circuit is not fully specified by the circuit elements and connection alone. To overcome this, the present sub-circuit matching technique also considers the nature of the input signals, which is explained below. 3) The extracted device sizes and netlist are typically imperfect, which make simulation based hypothesis testing difficult and requires robustness of automatic circuit analysis techniques. To overcome this, sub-circuit matching technique proposes an approximate/probabilistic sub-circuit matching algorithm/probabilistic sub-circuit matching technique to address this problem using a probabilistic graph matching technique.

In one embodiment, hierarchical levels of functional components are identified in an inputted mixed-signal circuit based on netlist, property of an input signal and a design knowledge base. This can be achieved by determining the property/nature of the input signal of each of the functional components, comparing the property of the input signal and the netlist with subcircuit patterns in the design knowledge base, and then identifying the hierarchical levels of functional components based on the comparison. This analysis assumes that the signal types of a chip pin are given by a datasheet.

The terms “mixed-signal circuit” and “mixed-signal integrated circuit” are being used interchangeably throughout the document. The term “netlist” is used to identify circuit elements and their connectivity information in the mixed-signal integrated circuit.

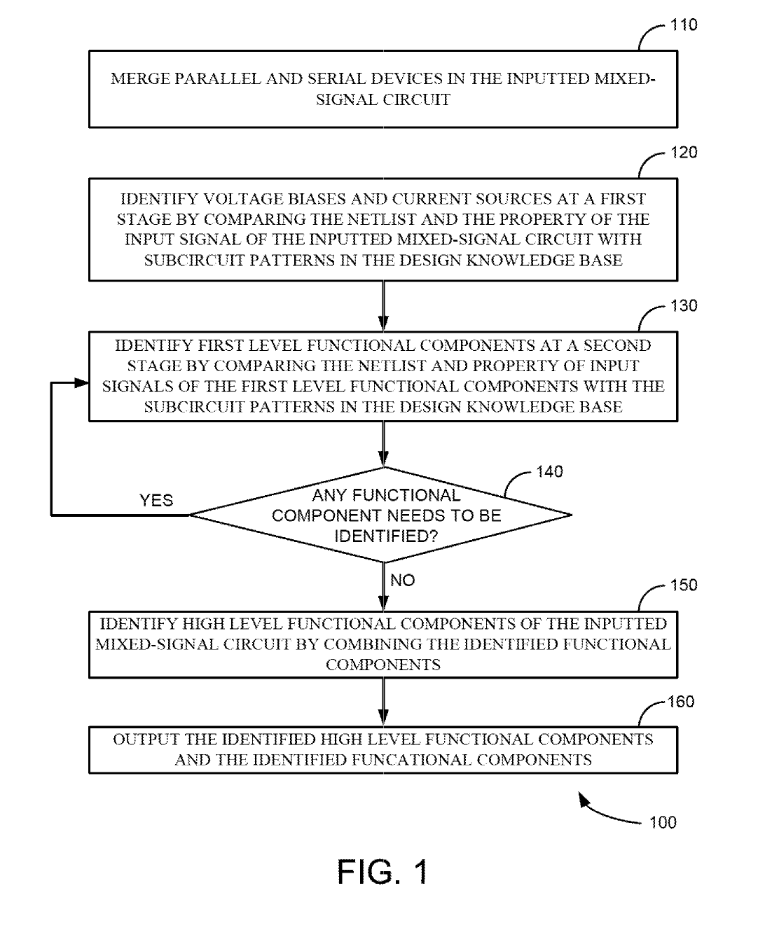

FIG. 1 is a flow diagram 100 of an automated method for mixed-signal circuit functional analysis, according to an embodiment of the present subject matter. The method identifies hierarchical levels of functional components in an inputted mixed-signal circuit based on netlist, property of an input signal and a design knowledge base.

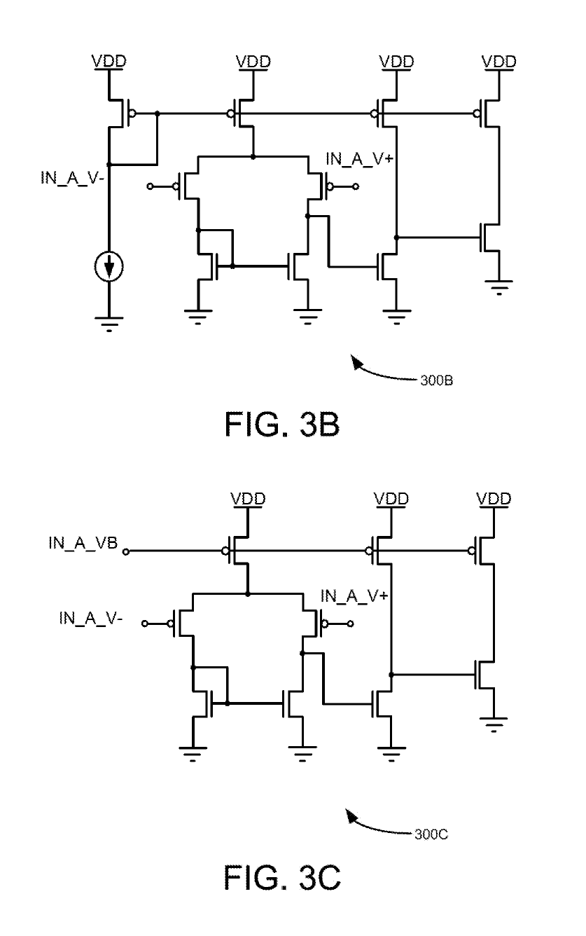

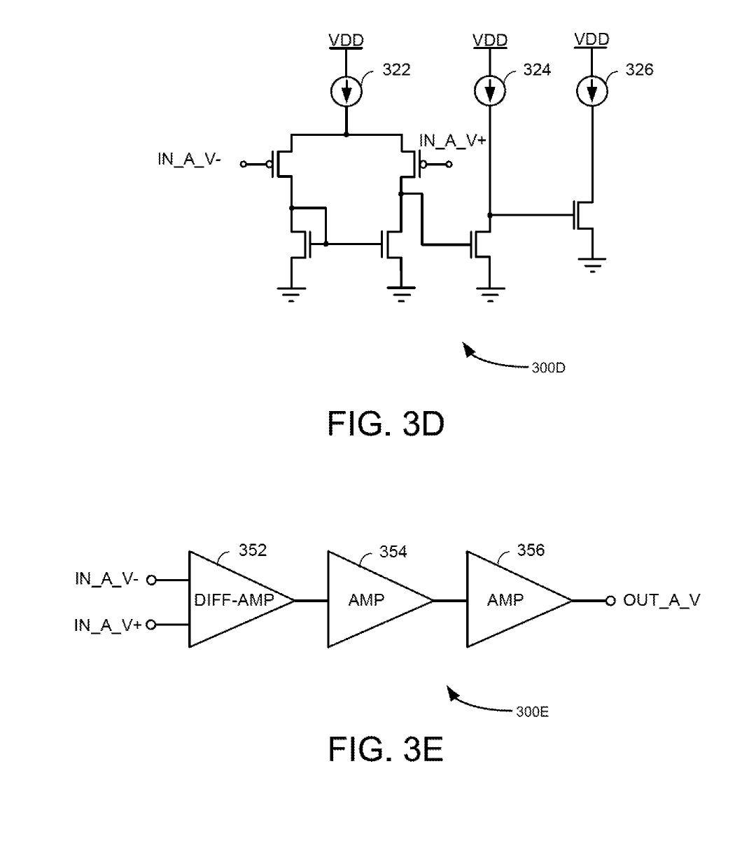

At block 110. parallel and serial devices in the inputted mixed-signal circuit are merged. This step is explained in detail using FIG. 3(b). The devices may represent either primitive components such transistors, capacitors, or higher-level devices such as adders, amplifiers, and/or register files. Each device v has a type, type(v), which distinguishes devices according to their function.

At block 120, voltage biases and current sources are identified at a first stage by comparing the netlist and the property of the input signal of the inputted mixed-signal circuit with subcircuit patterns in a design knowledge base. The netlist is extracted from the inputted mixed-signal chip. For example, the netlist can be inferred from imaging techniques, such as X-ray fluorescence tomography, micro computed tomography (MICRO-CT), and backside infrared imaging.

The design knowledge base can be built (i.e., manually or automatically) in the form of hierarchical schematics and corresponding netlists. For example, the design knowledge base includes subcircuit patterns of components including basic building blocks, amplifiers, operational amplifiers, comparators, data converters, interface circuits, power managements, clock and timing, voltage and current references, and/or radio frequency/intermediate frequency (RF/IF) circuits. Further, the basic building blocks include components such as diodes, transistors, resistors, capacitors, inductors, current sources. current mirrors, and/or switches. Also, the design knowledge base can be dynamically updated to add new subcircuit patterns. The identified subcircuits are replaced with voltage bias and/or current source symbols. Identifying voltage biases and current sources are explained in detail in FIGS. 3(c) and 3(d). The example design knowledge base including more components is shown in appendix A.

Further, multiple lower levels of functional components are identified by comparing the netlist and property of input signals of the functional components with the subcircuit patterns in the design knowledge base. The signal properties of matched output at each level are assigned as the input to functional components in a next level. The multiple lower levels of functional components are identified as shown in blocks 130 and 140. At block 130, first level functional components are identified at a second stage by comparing the netlist and property of input signals of the first level functional components with the subcircuit patterns in the design knowledge base. The identified subcircuits are then replaced with higher level abstract symbols (e.g., amplifiers, and data converters and the like). The signal properties of matched outputs of the first stage (i.e., at block 120) are assigned as the input to respective functional components in the netlist for further component matching. This step is explained in detail in FIG. 3(e).

At block 140, a check is made to determine whether any other functional components in the netlist need to be identified. If any other functional components in the netlist need to be identified, then the process repeats the block 130 for a next level of functional components until all the functional components in the netlist are identified. At block 150, higher level functional components of the inputted mixed-signal circuit are identified by combining the identified lower level functional components. The higher level functional components refer to a related collection of interconnected lower level components in the inputted mixed-signal circuit.

At block 160, the identified high level functional components, the identified lower level functional components and any unidentifiable circuits can be outputted. In one example, the identified high level functional components can include a top level chip function.

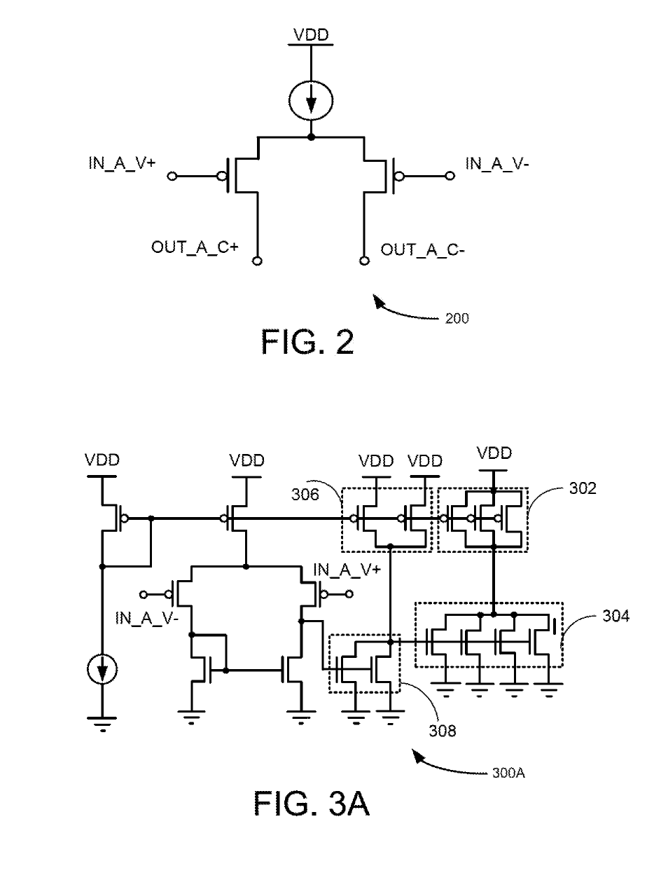

FIG. 2 illustrates an example schematic drawing showing a sub-circuit 200 which can function as a differential amplifier or a current switch, depending on the nature/property of the input signal, in the context of the present subject matter. One skilled in the art can understand that a single circuit, in the mixed-signal circuit, can serve different purposes according to the nature of its input signals. At the device level, the input signal on the gate of a pMOS transistor, depending on whether it is a voltage bias, a varying analog voltage signal, or a digital signal, can turn a transistor into a current source, a simple amplifier, or a digital switch. FIG. 2 illustrates one such sub-circuit which can be considered as an input stage of a differential amplifier if the inputs to the sub-circuit are differential analog voltage as shown in the FIG. 2. However, if the inputs are digital differential signal, the same sub-circuit can work as a current switch, a widely used sub-circuit in modern high speed D/A converters.

Therefore, above-mentioned method described in FIG. 1 considers the nature/property of the input signal for identifying the functional components. In the design knowledge base, the nature of the signal is labeled as input or output, analog or digital, current or voltage, constant or varying (to distinguish signals from biases). The enhanced sub-circuit matching algorithm of FIG. 1 treats the same device with different signal properties differently. This allows more accurate and faster sub-circuit identification. The above-mentioned method identifies hierarchical levels of functional components in an inputted mixed-signal circuit. In this case, the signal properties of the output nets of the previous stage will be assigned to the input of the next stage. Given the signal property at the pins of a chip, the above-mentioned method can thus infer the signal properties for the internal nets.

FIG. 3(a) is a schematic drawing 300(a) showing an example input mixed-signal circuit, in the context of the present subject matter. The algorithm/method performs the automatic functional analysis of the mixed-signal circuit as shown below in FIGS. 3(b)-3(e).

FIG. 3(b) is a schematic drawing 300(b) illustrating merging of parallel and serial devices in the input mixed-signal circuit of FIG. 3(a), according to an embodiment of the present subject matter. The devices may represent either primitive components such a transistors, capacitors, or higher-level devices such as adders or register files. Each device v has a type, type(v), which distinguishes devices according to their function. The parallel/serial transistors shown in blocks 302, 304, 306 and 308 of FIG. 3(a) are merged. The simplified mixed-signal circuit after merging is shown in FIG. 3(b). This can be achieved by sub-circuit matching of pre-defined simple parallel and serial circuits. The parallel and serial device structures are commonly used in mixed-signal circuit design and merging them may not affect functional analysis. This step is repeated till no thus structure can be found.

FIG. 3(c) is a schematic drawing 300(c) illustrating identifying voltage bias in the merged input mixed-signal circuit of FIG. 3(b), according to an embodiment of the present subject matter. The voltage bias (i.e., IN_A_VB as shown in FIG. 3C) is identified by comparing the netlist associated with the input mixed-signal circuit and the nature/property of the input signal with the subcircuit patterns in the design knowledge base. A voltage bias can be specified by various ways, such as a chip data sheet, a resistor string (typically implemented by diodes connected transistor), the left side of a current mirror (as in this example), or more complex circuits.

FIG. 3(d) is schematic drawing 300(d) illustrating identifying current sources in the input mixed-signal circuit of FIG. 3(c), according to an embodiment of the present subject matter. The current sources (322, 324, and 326) are identified by comparing the netlist associated with the input mixed-signal circuit and the nature/property of the input signal of the current sources with the subcircuit patterns in the design knowledge base. In this case, the nature/property of the input signal of the current sources is the output signal properties of the matched voltage bias circuit of FIG. 3(c). In the example shown in FIG. 3(d), the current sources can be the right side of current mirrors with voltage bias on the transistor gates.

FIG. 3(e) is a schematic drawing 300(e) illustrating identifying functional components in the input mixed-signal circuit of FIG. 3(d), according to an embodiment of the present subject matter. The functional components (i.e., a differential amplifier 352 and two common source amplifiers 354 and 356) are identified by comparing the netlist and property of input signals of the functional components with the subcircuit patterns in the design knowledge base. In this case, the signal properties of output of the matched current sources are assigned as the input to the respective functional components. In other words, the nature/property of the input signal of the functional components is the output signal properties of the respective matched current sources. Finally, the proposed method/algorithm identifies the top level function in the mixed-signal circuit using the identified functional components. In this example, the top level function is a three-stage op-amp which is the final analysis results of FIGS. 3(a)-3(e). Thus, the proposed method/algorithm identifies the hierarchical levels of functional components in the inputted mixed-signal circuit.

The method described above facilitates automatic mixed-signal circuit functional analysis by building a complete design knowledge base. The design knowledge base have the following characteristics:

1. Hierarchical: new knowledge can be added into the hierarchy with no effect on existing knowledge base, thus allow parallel development of this knowledge base.
2. Transparent to the analysis algorithm: Design knowledge is dynamically loaded and no change is needed in the circuit function analysis algorithm to work with new design knowledge. For example, a new type of current mirror can be added in the current mirror circuit family and the algorithm will search all potential current mirrors. All matched current mirror sub-circuits will be abstracted as current mirror before higher level abstraction.
3. The design knowledge is represented as circuit schematics and netlists in an open source tool X-Circuit. This design knowledge thus can be easily maintained, shared, and enhanced by users.

Also, a probabilistic matching can be incorporated into the automatic circuit functional analysis by generalizing the binary decision of sub-circuit matching to a soft decision. This probabilistic matching approach takes the percentage of matched nodes in the circuit graph as a probability score. For example, consider a standard three input NAND gate sub-circuit and an extracted netlist having bigger circuit than the NAND gate sub-circuit. Further, consider one of the connections is missed at the netlist extraction process. Therefore, a strict matching may result in no match. However, the probabilistic matching approach matches the two circuits by giving a matching score, for example, 10/14 or 71.4%.

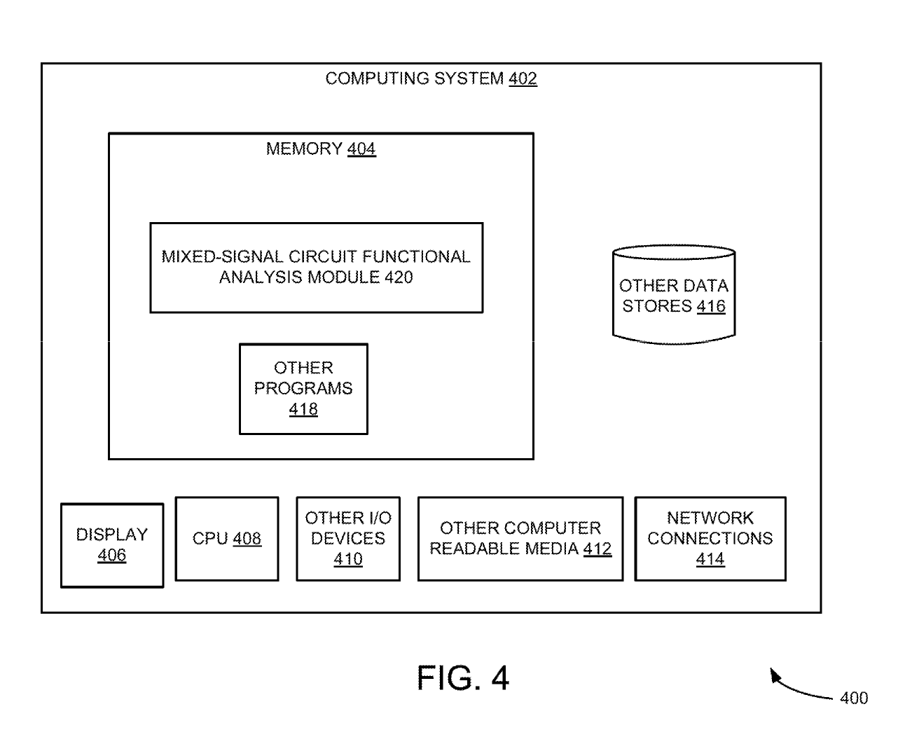

FIG. 4 is block diagram 400 of an example physical computing system 402 including the mixed-signal circuit functional analysis module 420 according to an example embodiment. In particular. FIG. 4 shows computing system 402 that may be utilized to implement the mixed-signal circuit functional analysis module 420. Note that one or more general purpose virtual or physical computer systems suitably instructed may be used to implement the mixed-signal circuit functional analysis module 420. In addition, computing system 402 may comprise one or more distinct computing systems/devices and may span distributed locations.

In the embodiment shown, computing system 402 may comprise computer memory (“memory”) 404, display 406. one or more Central Processing Units (“CPU”) 408, input/output devices 410 (e.g., keyboard, mouse, image capturing device, etc.), other computer-readable media 412, and network connections 414. The mixed-signal circuit functional analysis module 420 is shown residing in memory 404. The components of the mixed-signal circuit functional analysis module 420 may execute on one or more CPUs 408 and implement techniques described herein. Other code or programs 418 (e.g., an administrative interface, a Web server, and the like) may also reside in memory 404, and execute on one or more CPUs 408. Further, other data repositories, such as data store 416, may also reside in computing system 402. One or more of the components in FIG. 4 may not be present in any specific implementation. For example, some embodiments may not provide other computer readable media 412 or display 406.

The mixed-signal circuit functional analysis module 420 may interact via network with host computing systems in the cluster. The network may be any combination of media (e.g., twisted pair, coaxial, fiber optic, radio frequency), hardware (e.g., routers, switches, repeaters, transceivers), and protocols (e.g., TCP/IP, UDP, Ethernet, Wi-Fi, WiMAX) that facilitate communication to and from remotely situated humans and/or devices. In one embodiment, the mixed-signal circuit functional analysis module identifies hierarchicals level of functional components in an inputted mixed-signal circuit based on netlist, property of an input signal and a design knowledge base.

In addition, programming interfaces to the data stored as part of the mixed-signal circuit functional analysis module 420. such as in data store 416, can be available by standard mechanisms such as through C, C++, C#, and Java APIs; libraries for accessing files, databases, or other data repositories; through scripting languages such as XML; or through Web servers, FTP servers, or other types of servers providing access to stored data. Furthermore, in some embodiments, some or all of the components of the mixed-signal circuit functional analysis module 420 may be implemented or provided in other manners, such as at least partially in firmware and/or hardware, including, but not limited to one or more application-specific integrated circuits (“ASICs”), standard integrated circuits, controllers executing appropriate instructions, and including microcontrollers and/or embedded controllers, field-programmable gate arrays (“FPGAs”), complex programmable logic devices (“CPLDs”). and the like.

Some or all of the system components and/or data structures may also be stored as contents (e.g., as executable or other machine-readable software instructions or structured data) on a non-transitory computer-readable medium (e.g., as a hard disk; a memory; a computer network or cellular wireless network or other data transmission medium; or a portable media article to be read by an appropriate drive or via an appropriate connection, such as a DVD or flash memory device) so as to enable or configure the computer-readable medium and/or one or more associated computing systems or devices to execute or otherwise use or provide the contents to perform at least some of the described techniques. Some or all of the components and/or data structures may be stored on tangible, non-transitory storage mediums. Some or all of the system components and data structures may also be provided as data signals (e.g., by being encoded as part of a carrier wave or included as part of an analog or digital propagated signal) on a variety of computer-readable transmission mediums, which are then transmitted, including across wireless-based and wired/cable-based mediums, and may take a variety of forms (e.g., as part of a single or multiplexed analog signal, or as multiple discrete digital packets or frames). Such computer program products may also take other forms in other embodiments. Accordingly, embodiments of this disclosure may be practiced with other computer system configurations.

### APPENDIX A

1. Circuit design knowledge base

1.1 Basic Building Blocks
1.1.1 Diode
1.1.2 Transistor
1.1.3 Resistor
1.1.4 Capacitor
1.1.5 Inductor
1.1.6 Switches
   1.1.6.1 NMOS (metal-oxide-semiconductor) Switch
   1.1.6.2 PMOS Switch
   1.1.6.3 CMOS Switch
   1.1.6.4 Bipolar Switch
1.1.7 Current Sources
1.1.8 Current Mirrors
   1.1.8.1 Simply Current Mirrors
   1.1.8.2 Cascode Current Mirrors
   1.1.8.3 Cascode Current Mirrors with High Voltage Swing
   1.1.8.4 Wilson Current Mirrors
   1.1.8.5 Improved Wilson Current Mirrors

1.2 Data Converters
1.2.1 Analog to Digital Converter (ADC)
1.2.2 Digital to Analog Converter (DAC)
   1.2.2.1 Resistor String DAC (Kelvin Divider)
   1.2.2.2 Thermometer (fully-decoded) DAC
   1.2.2.3 Folded R-String DAC
   1.2.2.4 R-2R Ladder network DAC
   1.2.2.5 Current Steering DAC
   1.2.2.6 Charge/Current Scaling DAC
   1.2.2.7 Cyclic DAC
   1.2.2.8 Pipeline DAC
   1.2.2.9 Segmented DAC
   1.2.2.10 Oversampling (Delta-Sigma/Sigma-Delta) DAC
   1.2.2.11 Intentionally Nonlinear DACs
   1.2.2.12 Counting. Pulse width-Modulated DACs
1.2.3 Multiplexers

1.3 Amplifiers, Op-amps and Comparators
1.3.1 Op-amps
1.3.2 Comparators
1.3.3 Single Transistor amplifiers
1.3.4 Differential Amplifiers

1.4 Clock and Timing
1.4.1 Clock and Data Recovery/Retiming
1.4.2 Clock Generation and Distribution
   1.4.2.1 Ring Oscillator
1.4.3 Phase Lock Loop (PLL)
   1.4.3.1 Phase Detector
   1.4.3.2 Filter
   1.4.3.3 Voltage-controlled Oscillator

1.5 Interface
1.5.1 Output Buffer
   1.5.1.1 Voltage Follower
1.5.2 Level Transistors
1.5.3 Low Voltage Differential Signaling (LVDS) Circuit

1.6 Power Management
1.6.1 Current Sources
1.6.2 Linear Regulators
1.6.3 Switching Regulators

1.7 Reference
1.7.1 Current Reference
1.7.2 Voltage Reference
   1.7.2.1 Series Voltage Reference
   1.7.2.2 Shunt Voltage Reference

1.8 RF/IF
1.8.1 Downconverting Mixers
1.8.2 I/Q Demodulators
1.8.3 I/Q Modulators
1.8.4 Upconverting mixers

What is claimed is:

1. An automated method for mixed-signal circuit functional analysis, comprising:
identifying hierarchical levels of functional components in an inputted mixed-signal circuit based on netlist, property of an input signal and a design knowledge base.

2. The method of claim 1, wherein identifying the hierarchical levels of functional components in the inputted mixed-signal circuit, comprises:
determining the property of the input signal of each of the functional components;
comparing the property of the input signal and the netlist with subcircuit patterns in the design knowledge base; and
identifying the hierarchical levels of functional components based on the comparison.

3. The method of claim 1, wherein identifying the hierarchical levels of functional components in the inputted mixed-signal circuit, comprises:
merging parallel and serial devices in the inputted mixed-signal circuit;
identifying voltage biases and current sources by comparing the netlist and the property of the input signal of the inputted mixed-signal circuit with subcircuit patterns in the design knowledge base;
identifying multiple lower levels of functional components by comparing the netlist and property of input signals of the functional components with the subcircuit patterns in the design knowledge base, wherein signal properties of matched output at each level are assigned as the input to functional components in a next level; and
identifying high level functional components of the inputted mixed-signal circuit by combining the functional components identified in the multiple lower levels.

4. The method of claim 1, wherein the high level functional components comprise a related collection of interconnected functional components in the inputted mixed-signal circuit.

5. The method of claim 1, further comprising building the design knowledge base in the form of hierarchical schematics and corresponding netlists.

6. The method of claim 1, wherein the design knowledge base comprises subcircuit patterns of components selected from the group consisting of basic building blocks, amplifiers, operational amplifiers, comparators, data converters, interface circuits, power managements, clock and timing, voltage and current references, and radio frequency/intermediate frequency (RF/IF) circuits.

7. The method of claim 6, wherein the basic building blocks comprise components selected from the group consisting of diodes, transistors, resistors, capacitors, inductors, current sources, current mirrors, and switches.

8. The method of claim 1, wherein identifying the hierarchical levels of functional components comprises identifying the hierarchical levels of probabilistic functional components using probabilistic sub-circuit matching techniques.

9. The method of claim 1, wherein the design knowledge base is dynamically updated to add new subcircuit patterns.

10. A system for mixed-signal circuit functional analysis, comprising:
a processor;
memory coupled to the processor, wherein the memory includes a mixed-signal circuit functional analysis module to:
identify hierarchical levels of functional components in an inputted mixed-signal circuit based on netlist, property of an input signal and a design knowledge base.

11. The system of claim 10, wherein the mixed-signal circuit functional analysis module identifies the hierarchical levels of functional components in the inputted mixed-signal circuit, by:
merging parallel and serial devices in the inputted mixed-signal circuit;
identifying voltage biases and current sources by comparing the netlist and the property of the input signal of the inputted mixed-signal circuit with subcircuit patterns in the design knowledge base;
identifying multiple lower levels of functional components by comparing the netlist and property of input signals of the functional components with the subcircuit patterns in the design knowledge base, wherein signal properties of matched output at each level are assigned as the input to functional components in a next level; and
identifying high level functional components of the inputted mixed-signal circuit by combining the functional components identified in the multiple lower levels.

12. The system of claim 10, wherein the high level functional components comprise a related collection of interconnected functional components in the inputted mixed-signal circuit.

13. The system of claim 10, wherein the design knowledge base comprises subcircuit patterns of components selected from the group consisting of basic building blocks, amplifiers, operational amplifiers, comparators, data converters, interface circuits, power managements, clock and timing, voltage and current references, and radio frequency/intermediate frequency (RF/IF) circuits.

14. The system of claim 13, wherein the basic building blocks comprise components selected from the group consisting of diodes, transistors, resistors, capacitors, inductors, current sources, current mirrors, and switches.

15. The system of claim 10, wherein the mixed-signal circuit functional analysis module extracts the netlist from the inputted mixed-signal circuit.

16. The system of claim 10, wherein the mixed-signal circuit functional analysis module dynamically updates the design knowledge base to add new subcircuit patterns.

17. A non-transitory computer-readable storage medium including instructions that are configured, when executed by a computing system, to perform a method for mixed-signal circuit functional analysis, the method comprising:
identifying hierarchical levels of functional components in an inputted mixed-signal circuit based on netlist, property of an input signal and a design knowledge base.

18. The non-transitory computer-readable storage medium of claim 17, wherein identifying the hierarchical levels of functional components in the inputted mixed-signal circuit, comprises:
merging parallel and serial devices in the inputted mixed-signal circuit;
identifying voltage biases and current sources by comparing the netlist and the property of the input signal of the inputted mixed-signal circuit with subcircuit patterns in the design knowledge base;
identifying multiple lower levels of functional components by comparing the netlist and property of input signals of the functional components with the subcircuit patterns in the design knowledge base, wherein signal properties of matched output at each level are assigned as the input to functional components in a next level; and
identifying high level functional components of the inputted mixed-signal circuit by combining the functional components identified in the multiple lower levels.

19. The non-transitory computer-readable storage medium of claim 17, wherein the design knowledge base comprises subcircuit patterns of components selected from the group consisting of basic building blocks, amplifiers, operational amplifiers, comparators, data converters, interface circuits, power managements, clock and timing, voltage and current references, and radio frequency/intermediate frequency (RF/TF) circuits.

20. The non-transitory computer-readable storage medium of claim 17, wherein the design knowledge base is dynamically updated to add new subcircuit patterns.
